(19) United States
(12) Patent Application Publication
(10) Pub. No.: US 2023/0073105 A1
(43) Pub. Date: Mar. 9, 2023

(54) MULTIPLEXER, RADIO FREQUENCY CIRCUIT, AND COMMUNICATION DEVICE

(71) Applicant: Murata Manufacturing Co., Ltd., Kyoto (JP)

(72) Inventor: Masakazu TANI, Kyoto (JP)

(21) Appl. No.: 18/055,869

(22) Filed: Nov. 16, 2022

Related U.S. Application Data
(63) Continuation of application No. PCT/JP2021/019522, filed on May 24, 2021.

(30) Foreign Application Priority Data
Jun. 30, 2020 (JP) 2020-113557

(51) Int. Cl. H04L 27/20; H04L 27/233

(52) U.S. Cl. CPC H04L 27/20; H04L 27/2334

(57) ABSTRACT

Filter characteristics of a first filter are improved while suppressing degradation in filter characteristics of a second filter. A multiplexer includes a first terminal, a second terminal, a first filter, a second filter, and a capacitive element. The first filter and the second filter are connected to an antenna via the first terminal. The first filter includes a plurality of series arm resonators, a plurality of parallel arm resonators, and an inductor. The inductor is provided between the parallel arm resonator and ground. A first end portion of the capacitive element is connected to a first path at a position in between the series arm resonator that is the closest to the first terminal and the second terminal. A second end portion of the capacitive element is connected between the parallel arm resonator and the inductor.

### CROSS REFERENCE TO RELATED APPLICATION

This is a continuation of International Application No. PCT/JP2021/019522 filed on May 24, 2021 which claims priority from Japanese Patent Application No. 2020-113557 filed on Jun. 30, 2020. The contents of these applications are incorporated herein by reference in their entireties.

### BACKGROUND ART

### Technical Field

The present disclosure generally relates to multiplexers, radio frequency circuits, and communication devices, and more specifically, to a multiplexer, a radio frequency circuit, and a communication device, each of which includes two filters to be connected to an antenna.

Patent Document 1 describes a duplexer (multiplexer) including a transmission filter (first filter) connected between an antenna terminal and a transmission terminal and a reception filter (second filter) connected between the antenna terminal and a reception terminal.

The transmission filter is a ladder filter including a plurality of series arm resonators and a plurality of parallel arm resonators. In the transmission filter, an inductor is connected between an earth potential (ground) and two parallel arm resonators of the plurality of parallel arm resonators on the antenna terminal side, and a coupling capacitor (capacitive element) is connected between the antenna terminal and one end portion of the inductor, which is opposite to the end portion connected to the earth potential.
Patent Document 1: International Publication No. 2015/040921

### BRIEF SUMMARY

In the duplexer described in Patent Document 1, the coupling capacitor described above enables to improve filter characteristics of the transmission filter. However, there is a possibility of causing degradation in filter characteristics of the reception filter.

The present disclosure provides a multiplexer, a radio frequency circuit, and a communication device, each of which enables to improve the filter characteristics of the first filter while suppressing the degradation in filter characteristics of the second filter.

A multiplexer according to one aspect of the present disclosure includes a first terminal, a second terminal, a first filter, a second filter, and a capacitive element. The first terminal is connected to an antenna. The second terminal is connected to an amplifier. The first filter and the second filter are connected to the antenna via the first terminal. The capacitive element includes a first end portion and a second end portion. The first filter includes a plurality of series arm resonators, a plurality of parallel arm resonators, and at least one inductor. The plurality of series arm resonators are provided on a first path that connects the first terminal and the second terminal. The plurality of parallel arm resonators are provided on a plurality of second paths respectively connecting a plurality of nodes on the first path and ground. The at least one inductor is provided between at least one parallel arm resonator of the plurality of parallel arm resonators and the ground. The first end portion of the capacitive element is connected to the first path at a position in between the second terminal and a series arm resonator that is closest to the first terminal among the plurality of series arm resonators. The second end portion of the capacitive element is connected between the parallel arm resonator and the inductor.

A radio frequency circuit according to one aspect of the present disclosure includes the multiplexer, a first amplifier, and a second amplifier. The first amplifier serves as the amplifier and is connected to the first filter. The second amplifier is connected to the second filter.

A communication device according to one aspect of the present disclosure includes the radio frequency circuit and a signal processing circuit. The signal processing circuit is connected to the radio frequency circuit.

According to the multiplexer, the radio frequency circuit, and the communication device according to the foregoing aspects of the present disclosure, it becomes possible to improve the filter characteristics of the first filter while suppressing the degradation in filter characteristics of the second filter.

### BRIEF DESCRIPTION OF THE DRAWINGS

FIG. 1 is a circuit diagram of a multiplexer, a radio frequency circuit, and a communication device according to an embodiment.

FIG. 2 is a circuit diagram of the multiplexer described above.

FIG. 3A is a graph illustrating the impedance characteristic of a first filter included in the multiplexer described above. FIG. 3B is a graph expanding part of FIG. 3A.

FIG. 4A is a graph illustrating the insertion loss of the first filter included in the multiplexer described above. FIG. 4B is a graph expanding part of FIG. 4A.

FIG. 5 is a circuit diagram of a multiplexer according to a modified example 1 of the embodiment.

FIG. 6A is a graph illustrating the insertion loss of a DETAILED DESCRIPTION first filter included in the multiplexer described above. FIG. 6B is a graph expanding part of FIG. 6A.

FIG. 7 is a schematic diagram illustrating a layout of a multiplexer according to a modified example 2 of the embodiment.

### DETAILED DESCRIPTION

Drawings being referred in the following embodiment and the like are all schematic diagrams, and each ratio of sizes or thicknesses of constituent elements in the drawings does not necessarily reflect the actual ratio of dimensions.

### EMBODIMENT

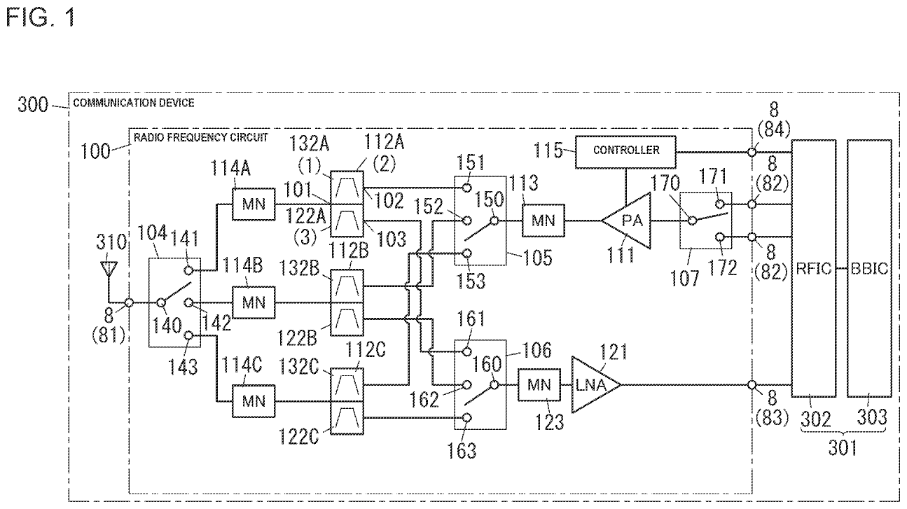

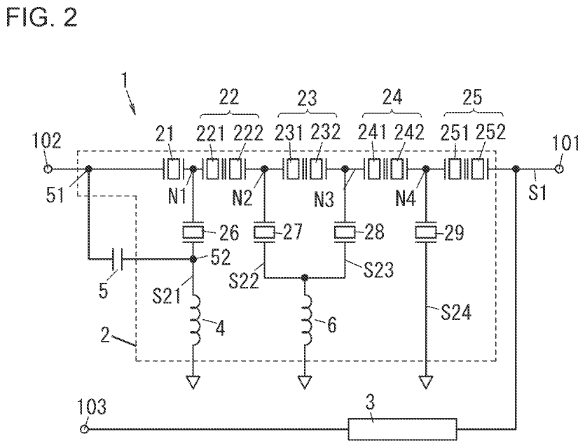

As illustrated in FIG. 1 and FIG. 2, a multiplexer 1 according to an embodiment includes a first terminal 101, a second terminal 102, a first filter 2, a second filter 3, and a capacitive element 5. The first terminal 101 is connected to an antenna 310. The second terminal 102 is connected to an amplifier (for example, a power amplifier 111). The first filter 2 and the second filter 3 are connected to the antenna 310 via the first terminal 101. The capacitive element 5 includes a first end portion 51 and a second end portion 52. The first filter 2 includes a plurality of series arm resonators (first to fifth series arm resonators 21 to 25), a plurality of parallel arm resonators (first to fourth parallel arm resonators 26 to 29), and at least one inductor 4. The plurality of series arm resonators are provided on a first path S1 connecting the first terminal 101 and the second terminal 102. The plurality of parallel arm resonators are provided on a plurality of second paths S21 to S24 that respectively connect a plurality of nodes N1 to N4 on the first path S1 and a ground. At least one inductor 4 is provided between at least one parallel arm resonator (first parallel arm resonator 26) of the plurality of parallel arm resonators and the ground. The first end portion 51 of the capacitive element 5 is connected to the first path S1 at a position between the second terminal 102 and the series arm resonator (fifth series arm resonator 25) that is the closest to the first terminal 101 among the plurality of series arm resonators. The second end portion 52 of the capacitive element 5 is connected between the parallel arm resonator (first parallel arm resonator 26) and the inductor 4.

By providing the capacitive element 5 at a specific position of the first filter 2, the multiplexer 1 according to the embodiment enables to improve filter characteristics of the first filter 2 while suppressing degradation in filter characteristics of the second filter 3.

Hereinafter, the multiplexer 1, a radio frequency circuit 100, and a communication device 300 according to the embodiment are described with reference to FIG. 1 to FIG. 7.

### (1) CIRCUIT CONFIGURATIONS OF MULTIPLEXER, RADIO FREQUENCY CIRCUIT, AND COMMUNICATION DEVICE

The multiplexer 1 according to the embodiment, for example, is used in the radio frequency circuit 100. The radio frequency circuit 100, for example, is used in a multimode/multiband-compatible communication device 300. The communication device 300, for example, is a mobile phone (for example, a smartphone). However, the communication device 300 is not limited thereto and may, for example, be a wearable terminal (for example, a smart watch). The radio frequency circuit 100, for example, is a circuit compatible with the 4G (fourth generation mobile telecommunications) standard or the 5G (fifth generation mobile telecommunications) standard. The 4G standard, for example, is 3GPP LTE (Long Term Evolution) standard. The 5G standard, for example, is 5G NR (New Radio). The radio frequency circuit 100 is a circuit compatible with carrier aggregation and dual connectivity.

The radio frequency circuit 100, for example, is configured in such a manner as to amplify a transmission signal (radio frequency signal) input from a signal processing circuit 301 and output to the antenna 310. Further, the radio frequency circuit 100 is configured in such a manner as to amplify a reception signal (radio frequency signal) input from the antenna 310 and output to the signal processing circuit 301. The signal processing circuit 301 is not a constituent element of the radio frequency circuit 100 and is a constituent element of the communication device 300 including the radio frequency circuit 100. The radio frequency circuit 100, for example, is controlled by the signal processing circuit 301 included in the communication device 300. The communication device 300 includes the radio frequency circuit 100 and the signal processing circuit 301. The communication device 300 further includes the antenna 310. The communication device 300 further includes a circuit board (not illustrated) on which the radio frequency circuit 100 is mounted. The circuit board, for example, is a printed wiring board. The circuit board includes a ground electrode to which a ground potential is given.

The signal processing circuit 301, for example, includes a RF signal processing circuit 302 and a baseband signal processing circuit 303. The RF signal processing circuit 302, for example, is a RFIC (Radio Frequency Integrated Circuit) and performs signal processing on a radio frequency signal. The RF signal processing circuit 302, for example, performs signal processing on a radio frequency signal output from the baseband signal processing circuit 303 (transmission signal) using up-converting and the like, and outputs a radio frequency signal on which the signal processing has been performed. Further, the RF signal processing circuit 302, for example, performs signal processing on a radio frequency signal output from the radio frequency circuit 100 (reception signal) using down-converting and the like, and outputs a radio frequency signal, on which the signal processing has been performed, to the baseband signal processing circuit 303. The baseband signal processing circuit 303, for example, is a BBIC (Baseband Integrated Circuit). The baseband signal processing circuit 303 generates an I-phase signal and a Q-phase signal from a baseband signal. The baseband signal, for example, is an audio signal, an image signal, or the like input from outside. The baseband signal processing circuit 303 performs IQ modulation processing by combining the I-phase signal and the Q-phase signal and outputs a transmission signal. At this time, the transmission signal is generated as a modulated signal (IQ signal) in which a carrier signal of a predetermined frequency is amplitude-modulated using a longer period than the period of this carrier signal. The reception signal processed in the baseband signal processing circuit 303, for example, is used as an image signal for image display or as an audio signal for calls. The radio frequency circuit 100 transmits radio frequency signals (reception signal and transmission signal) between the antenna 310 and the RF signal processing circuit 302 of the signal processing circuit 301.

The radio frequency circuit 100 includes a power amplifier 111 and a low-noise amplifier 121. Further, the radio frequency circuit 100 further includes a plurality (three in the illustrated example) of transmission filters 112A to 112C and a plurality (three in the illustrated example) of reception filters 122A to 122C. Further, the radio frequency circuit 100 further includes an output matching circuit 113, an input matching circuit 123, a plurality (three in the illustrated example) of matching circuits 114A to 114C. Further, the radio frequency circuit 100 further includes a first switch 104, a second switch 105, a third switch 106, and a fourth switch 107. Further, the radio frequency circuit 100 further includes a controller 115.

Further, the radio frequency circuit 100 further includes a plurality of external connection terminals 8. The plurality of external connection terminals 8 include an antenna terminal 81, a plurality (two in the illustrated example) of signal input terminals 82, a signal output terminal 83, a control terminal 84, and a plurality of ground terminals (not illustrated). The plurality of ground terminals are terminals to which the ground potential is given by being electrically connected to ground electrodes of the foregoing circuit board included in the communication device 300.

The power amplifier 111 is provided on a signal path for transmission signal. The power amplifier 111 includes an input terminal, an output terminal, and a power terminal. The power amplifier 111 amplifies a transmission signal of a first frequency band input to the input terminal and outputs to the output terminal. The first frequency band, for example, includes a first communication band, a second communication band, and a third communication band. The first communication band corresponds to a transmission signal that passes through the transmission filter 112A and, for example, is Band 3 of the 3GPP LTE standard. The second communication band corresponds to a transmission signal that passes through the transmission filter 112B and, for example, is Band 1 of the 3GPP LTE standard. The third communication band corresponds to a transmission signal that passes through the transmission filter 112C and, for example, is Band 66 of the 3GPP LTE standard.

The input terminal of the power amplifier 111 is connected to a common terminal 170 of the fourth switch 107. A plurality of selection terminals 171 and 172 of the fourth switch 107 are connected to the plurality of signal input terminals 82, respectively. The input terminal of the power amplifier 111 is connected to the signal processing circuit 301 via the fourth switch 107 and the plurality of signal input terminals 82. The plurality of signal input terminals 82 are terminals for inputting a radio frequency signal (transmission signal) received from an external circuit (for example, the signal processing circuit 301) to the radio frequency circuit 100. The output terminal of the power amplifier 111 is connected to a common terminal 150 of the second switch 105 via the output matching circuit 113. The power terminal of the power amplifier 111 is connected to the controller 115. The power amplifier 111, for example, is controlled by the controller 115. In the radio frequency circuit 100 according to the embodiment, the power amplifier 111 is a first amplifier connected to the foregoing first filter 2 (transmission filter 112A).

The low-noise amplifier 121 is provided on a signal path for reception signal. The low-noise amplifier 121 includes an input terminal and an output terminal. The low-noise amplifier 121 amplifies a reception signal of a second frequency band input to the input terminal and outputs from the output terminal. The second frequency band, for example, includes a fourth communication band, a fifth communication band, and a sixth communication band. The fourth communication band corresponds to a reception signal that passes through the reception filter 122A and, for example, is Band 3 of the 3GPP LTE standard. The fifth communication band corresponds to a transmission signal that passes through the reception filter 122B and, for example, is Band 1 of the 3GPP LTE standard. The sixth communication band corresponds to a transmission signal that passes through the reception filter 122C and, for example, is Band 66 of the 3GPP LTE standard.

The input terminal of the low-noise amplifier 121 is connected to a common terminal 160 of the third switch 106 via the input matching circuit 123. The output terminal of the low-noise amplifier 121 is connected to the signal output terminal 83. The output terminal of the low-noise amplifier 121, for example, is connected to the signal processing circuit 301 via the signal output terminal 83. The signal output terminal 83 is a terminal for outputting a radio frequency signal (reception signal) received from the low-noise amplifier 121 to an external circuit (for example, the signal processing circuit 301). In the radio frequency circuit 100 according to the embodiment, the low-noise amplifier 121 is a second amplifier connected to the foregoing second filter 3 (reception filter 122A).

The transmission filter 112A, for example, is a filter whose pass band is a transmission band of the first communication band. The transmission filter 112B, for example, is a filter whose pass band is a transmission band of the second communication band. The transmission filter 112C, for example, is a filter whose pass band is a transmission band of the third communication band. The reception filter 122A, for example, is a filter whose pass band is a reception band of the fourth communication band. The reception filter 122B, for example, is a filter whose pass band is a reception band of the fifth communication band. The reception filter 122C, for example, is a filter whose pass band is a reception band of the sixth communication band. In the radio frequency circuit 100 according to the embodiment, the transmission filter 112A and the reception filter 122A form a duplexer 132A, the transmission filter 112B and the reception filter 122B form a duplexer 132B, and the transmission filter 112C and the reception filter 122C form a duplexer 132C. In the radio frequency circuit 100 according to the embodiment, the duplexer 132A is the multiplexer 1, the transmission filter 112A is the first filter 2, and the reception filter 122A is the second filter 3.

The first switch 104 includes a common terminal 140 and a plurality (three in the illustrated example) of selection terminals 141 to 143. The common terminal 140 is connected to the antenna terminal 81. The antenna terminal 81 is connected to the antenna 310. The selection terminal 141 is connected to the output terminal of the transmission filter 112A and the input terminal of the reception filter 122A. The selection terminal 142 is connected to the output terminal of the transmission filter 112B and the input terminal of the reception filter 122B. The selection terminal 143 is connected to the output terminal of the transmission filter 112C and the input terminal of the reception filter 122C. The first switch 104, for example, is a switch that can connect the common terminal 140 and at least one of the plurality of selection terminals 141 to 143. Here, the first switch 104, for example, is a switch that can have one-to-one connection and one-to-many connection.

The first switch 104 is provided on both the signal path for transmission signal and the signal path for reception signal. More specifically, the first switch 104 is provided on a signal path for transmission signal, along which the fourth switch 107, the power amplifier 111, the output matching circuit 113, the second switch 105, the transmission filter 112A, and the matching circuit 114A are provided. Further, the first switch 104 is provided on a signal path for transmission signal, along which the fourth switch 107, the power amplifier 111, the output matching circuit 113, the second switch 105, the transmission filter 112B, and the matching circuit 114B are provided. Further, the first switch 104 is provided on a signal path for transmission signal, along which the fourth switch 107, the power amplifier 111, the output matching circuit 113, the second switch 105, the transmission filter 112C, and the matching circuit 114C are provided.

Further, the first switch 104 is provided on a signal path for reception signal, along which the matching circuit 114A, the reception filter 122A, the third switch 106, the input matching circuit 123, and the low-noise amplifier 121 are provided. Further, the first switch 104 is provided on a signal path for reception signal, along which the matching circuit 114B, the reception filter 122B, the third switch 106, the input matching circuit 123, and the low-noise amplifier 121 are provided. Further, the first switch 104 is provided on a signal path for reception signal, along which the matching circuit 114C, the reception filter 122C, the third switch 106, the input matching circuit 123, and the low-noise amplifier 121 are provided.

The first switch 104, for example, is controlled by the signal processing circuit 301. The first switch 104 switches the state of connection between the common terminal 140 and the plurality of selection terminals 141 to 143 in accordance with a control signal from the RF signal processing circuit 302 of the signal processing circuit 301. The first switch 104, for example, is a switch IC (Integrated Circuit).

The second switch 105 includes a common terminal 150 and a plurality (three in the illustrated example) of selection terminals 151 to 153. The common terminal 150 is connected to the output terminal of the power amplifier 111 via the output matching circuit 113. The selection terminal 151 is connected to the input terminal of the transmission filter 112A. The selection terminal 152 is connected to the input terminal of the transmission filter 112B. The selection terminal 153 is connected to the input terminal of the transmission filter 112C. The second switch 105, for example, is a switch that can connect the common terminal 150 and at least one of the plurality of selection terminals 151 to 153. Here, the second switch 105, for example, is a switch that can have one-to-one connection and one-to-many connection. The second switch 105 is a switch having the capability of switching between signal paths for a plurality of transmission signals of communication bands different from each other.

The second switch 105, for example, is controlled by the signal processing circuit 301. The second switch 105 switches the state of connection between the common terminal 150 and the plurality of selection terminals 151 to 153 in accordance with a control signal from the RF signal processing circuit 302 of the signal processing circuit 301. The second switch 105, for example, is a switch IC.

The third switch 106 includes a common terminal 160 and a plurality (three in the illustrated example) of selection terminals 161 to 163. The common terminal 160 is connected to the input terminal of the low-noise amplifier 121 via the input matching circuit 123. The selection terminal 161 is connected to the output terminal of the reception filter 122A. The selection terminal 162 is connected to the output terminal of the reception filter 122B. The selection terminal 163 is connected to the output terminal of the reception filter 122C. The third switch 106, for example, is a switch that can connect the common terminal 160 and at least one of the plurality of selection terminals 161 to 163. Here, the third switch 106, for example, is a switch that can have one-to-one connection and one-to-many connection. The third switch 106 is a switch having the capability of switching between signal paths for a plurality of reception signals of communication bands different from each other.

The third switch 106, for example, is controlled by the signal processing circuit 301. The third switch 106 switches the state of connection between the common terminal 160 and the plurality of selection terminals 161 to 163 in accordance with a control signal from the RF signal processing circuit 302 of the signal processing circuit 301. The third switch 106, for example, is a switch IC.

The fourth switch 107 includes a common terminal 170 and a plurality (two in the illustrated example) of selection terminals 171 and 172. The common terminal 170 is connected to the input terminal of the power amplifier 111. Each of the plurality of selection terminals 171 and 172 is connected to a corresponding signal input terminal 82 of the plurality of signal input terminals 82.

The fourth switch 107, for example, is controlled by the signal processing circuit 301. The fourth switch 107 switches the state of connection between the common terminal 170 and the plurality of selection terminals 171 and 172 in accordance with a control signal from the RF signal processing circuit 302 of the signal processing circuit 301. The fourth switch 107, for example, is a switch IC.

The output matching circuit 113 is provided on the signal path between the output terminal of the power amplifier 111 and the common terminal 150 of the second switch 105. The output matching circuit 113 is a circuit for providing impedance matching between the power amplifier 111 and the transmission filters 112A to 112C. The output matching circuit 113, for example, is made up of a single inductor. However, the configuration of the output matching circuit 113 is not limited thereto, and the output matching circuit 113 may, for example, include a plurality of inductors and a plurality of capacitors in some cases.

The input matching circuit 123 is provided on the signal path between the input terminal of the low-noise amplifier 121 and the common terminal 160 of the third switch 106. The input matching circuit 123 is a circuit for providing impedance matching between the low-noise amplifier 121 and the reception filters 122A to 122C. The input matching circuit 123, for example, is made up of a single inductor. However, the configuration of the input matching circuit 123 is not limited thereto, and the input matching circuit 123 may, for example, include a plurality of inductors and a plurality of capacitors in some cases.

The matching circuit 114A is provided on the signal path between the selection terminal 141 of the first switch 104 and two terminals, which are the output terminal of the transmission filter 112A and the input terminal of the reception filter 122A. The matching circuit 114A is a circuit for providing impedance matching between the first switch 104 and two filters, which are the transmission filters 112A and the reception filter 122A. The matching circuit 114A, for example, is made up of a single inductor. However, the configuration of the matching circuit 114A is not limited thereto, and the matching circuit 114A may, for example, include a plurality of inductors and a plurality of capacitors in some cases.

The matching circuit 114B is provided on the signal path between the selection terminal 142 of the first switch 104 and two terminals, which are the output terminal of the transmission filter 112B and the input terminal of the reception filter 122B. The matching circuit 114B is a circuit for providing impedance matching between the first switch 104 and two filters, which are the transmission filters 112B and the reception filter 122B. The matching circuit 114B, for example, is made up of a single inductor. However, the configuration of the matching circuit 114B is not limited thereto, and the matching circuit 114B may, for example, include a plurality of inductors and a plurality of capacitors in some cases.

The matching circuit 114C is provided on the signal path between the selection terminal 143 of the first switch 104 and two terminals, which are the output terminal of the transmission filter 112C and the input terminal of the reception filter 122C. The matching circuit 114C is a circuit for providing impedance matching between the first switch 104 and two filters, which are the transmission filters 112C and the reception filter 122C. The matching circuit 114C, for example, is made up of a single inductor. However, the configuration of the matching circuit 114C is not limited thereto, and the matching circuit 114C may, for example, include a plurality of inductors and a plurality of capacitors in some cases.

The controller 115 is connected to the power terminal of the power amplifier 111. The controller 115, for example, is connected to the signal processing circuit 301 via the control terminal 84. The control terminal 84 is a terminal for inputting a control signal received from an external circuit (for example, the signal processing circuit 301) to the controller 115. The controller 115 controls the power amplifier 111 based on the control signal obtained from the control terminal 84. The controller 115 controls the power amplifier 111 in accordance with the control signal from the RF signal processing circuit 302 of the signal processing circuit 301.

As described above, the multiplexer 1 includes the first filter 2 and the second filter 3. Further, the multiplexer 1 further includes the first terminal 101, the second terminal 102, and the third terminal 103. Further, the multiplexer 1 further includes the capacitive element 5.

The first terminal 101 is an output terminal of the transmission filter 112A that serves as the first filter 2. Further, the first terminal 101 is an input terminal of the reception filter 122A that serves as the second filter 3. That is to say, the first terminal 101 is a common terminal of the first filter 2 and the second filter 3. The first terminal 101 is connected to the antenna 310. That is to say, the first filter 2 and the second filter 3 are connected to the antenna 310 via the first terminal 101. The second terminal 102 is an input terminal of the transmission filter 112A that serves as the first filter 2. The second terminal 102 is connected to the power amplifier 111 that serves as the first amplifier. The third terminal 103 is an output terminal of the reception filter 122A that serves as the second filter 3. The third terminal 103 is connected to the low-noise amplifier 121 that serves as the second amplifier.

As illustrated in FIG. 2, the first filter 2 (transmission filter 112A) is a ladder filter. The first filter 2 includes a plurality (five in the illustrated example) of series arm resonators, a plurality (four in the illustrated example) of parallel arm resonators, and a plurality (two in the illustrated example) of inductors 4 and 6.

As illustrated in FIG. 2, the plurality of series arm resonators include a first series arm resonator 21, a second series arm resonator 22, a third series arm resonator 23, a fourth series arm resonator 24, and a fifth series arm resonator 25. The plurality of series arm resonators are provided on a first path S1 that connects the first terminal 101 and the second terminal 102. The plurality of series arm resonators are connected in series on the first path S1. The plurality of series arm resonators are arranged in the order of, from the second terminal 102 side, the first series arm resonator 21, the second series arm resonator 22, the third series arm resonator 23, the fourth series arm resonator 24, and the fifth series arm resonator 25.

The second series arm resonator 22 includes a first segmented resonator 221 and a second segmented resonator 222. The first segmented resonator 221 and the second segmented resonator 222 are connected in series. The first segmented resonator 221 and the second segmented resonator 222 are resonators formed by dividing the second series arm resonator 22, and are arranged in succession and connected to each other without necessarily any parallel arm resonator interposed therebetween. The number of the segmented resonators is not limited to two and may be three or more. Further, the second series arm resonator 22 does not need to be divided into two or more segmented resonators.

The third series arm resonator 23 includes a first segmented resonator 231 and a second segmented resonator 232. The first segmented resonator 231 and the second segmented resonator 232 are connected in series. The first segmented resonator 231 and the second segmented resonator 232 are resonators formed by dividing the third series arm resonator 23, and are arranged in succession and connected to each other without necessarily any parallel arm resonator interposed therebetween. The number of the segmented resonators is not limited to two and may be three or more. Further, the third series arm resonator 23 does not need to be divided into two or more segmented resonators.

The fourth series arm resonator 24 includes a first segmented resonator 241 and a second segmented resonator 242. The first segmented resonator 241 and the second segmented resonator 242 are connected in series. The first segmented resonator 241 and the second segmented resonator 242 are resonators formed by dividing the fourth series arm resonator 24, and are arranged in succession and connected to each other without necessarily any parallel arm resonator interposed therebetween. The number of the segmented resonators is not limited to two and may be three or more. Further, the fourth series arm resonator 24 does not need to be divided into two or more segmented resonators.

The fifth series arm resonator 25 includes a first segmented resonator 251 and a second segmented resonator 252. The first segmented resonator 251 and the second segmented resonator 252 are connected in series. The first segmented resonator 251 and the second segmented resonator 252 are resonators formed by dividing the fifth series arm resonator 25, and are arranged in succession and connected to each other without necessarily any parallel arm resonator interposed therebetween. The number of the segmented resonators is not limited to two and may be three or more. Further, the fifth series arm resonator 25 does not need to be divided into two or more segmented resonators.

As illustrated in FIG. 2, the plurality of parallel arm resonators include a first parallel arm resonator 26, a second parallel arm resonator 27, a third parallel arm resonator 28, and a fourth parallel arm resonator 29.

The first parallel arm resonator 26 is provided between the first path S1 and the ground. More specifically, the first parallel arm resonator 26 is provided on a second path S21 between a first node N1 on the first path S1 and the ground. The first node N1 is positioned on the first path S1 between the first series arm resonator 21 and the second series arm resonator 22.

The second parallel arm resonator 27 is provided between the first path S1 and the ground. More specifically, the second parallel arm resonator 27 is provided on a second path S22 between a second node N2 on the first path S1 and the ground. The second node N2 is positioned on the first path S1 between the second series arm resonator 22 and the third series arm resonator 23.

The third parallel arm resonator 28 is provided between the first path S1 and the ground. More specifically, the third parallel arm resonator 28 is provided on a second path S23 between a third node N3 on the first path S1 and the ground. The third node N3 is positioned on the first path S1 between the third series arm resonator 23 and the fourth series arm resonator 24.

The fourth parallel arm resonator 29 is provided between the first path S1 and the ground. More specifically, the fourth parallel arm resonator 29 is provided on a second path S24 between a fourth node N4 on the first path S1 and the ground. The fourth node N4 is positioned on the first path S1 between the fourth series arm resonator 24 and the fifth series arm resonator 25.

Each of the plurality of series arm resonators and the plurality of parallel arm resonators, for example, is made up of one or more acoustic wave resonators.

That is to say, the first filter 2 is an acoustic wave filter. The acoustic wave filter, for example, is a surface acoustic wave filter that uses a surface acoustic wave. In the surface acoustic wave filter, each of the plurality of series arm resonators and the plurality of parallel arm resonators, for example, is a SAW (surface acoustic wave) resonator.

The inductor 4 is provided on the second path S21. More specifically, the inductor 4 is connected in series to the first parallel arm resonator 26 described above on the second path S21. That is to say, on the second path S21, a series circuit of the first parallel arm resonator 26 and the inductor 4 is connected between the first node N1 and the ground.

The inductor 6 is provided on the second paths S22 and S23. More specifically, the inductor 6 is connected in series to the second parallel arm resonator 27 described above on the second path S22. That is to say, on the second path S22, a series circuit of the second parallel arm resonator 27 and the inductor 6 is connected between the second node N2 and the ground. Further, the inductor 6 is connected in series to the third parallel arm resonator 28 described above on the second path S23. That is to say, on the second path S23, a series circuit of the third parallel arm resonator 28 and the inductor 6 is connected between the third node N3 and the ground. In short, the inductor 6 is connected in series to both the second parallel arm resonator 27 and the third parallel arm resonator 28.

The inductors 4 and 6 enable to form an attenuation pole on the high frequency side above the pass band of the first filter 2. Particularly, according to the inductor 6, it becomes possible to form an attenuation pole with an inductance (L value) smaller than the inductor 4.

As is the case with the first filter 2, the second filter 3 (reception filter 122A), for example, is a ladder filter made up of a plurality of resonators. The second filter 3 is connected between the first terminal 101 and the third terminal 103. The second filter 3 is not limited to a ladder filter and may, for example, alternatively be a filter of longitudinally coupled resonators or a filter formed by combining a ladder filter and a filter of longitudinally coupled resonators.

The capacitive element 5, for example, is made up of a single capacitor. The capacitive element 5 includes a first end portion 51 and a second end portion 52. The first end portion 51 of the capacitive element 5 is connected to the first path S1 at a position in between the second terminal 102 and the fifth series arm resonator 25 that is the closest to the first terminal 101 among the plurality of series arm resonators. More specifically, the first end portion 51 of the capacitive element 5 is connected to the first path S1 at a position in between the second terminal 102 and the first series arm resonator 21 that is the closest to the second terminal 102 among the plurality of series arm resonators. The second end portion 52 of the capacitive element 5 is connected (at a connecting point) between the inductor 4 and the first parallel arm resonator 26 of the plurality of parallel arm resonators, to which the inductor 4 is connected in series. That is to say, in the multiplexer 1 according to the embodiment, the capacitive element 5 is connected in parallel to two or more resonators including the first parallel arm resonator 26. More specifically, the capacitive element 5 is connected in parallel to the first series arm resonator 21 and the first parallel arm resonator 26.

In the multiplexer 1 according to the embodiment, the first filter 2 and the capacitive element 5 described above are formed from a single chip. That is to say, the chip described above includes the first filter 2 and the capacitive element 5.

### (2) CHARACTERISTICS OF MULTIPLEXER

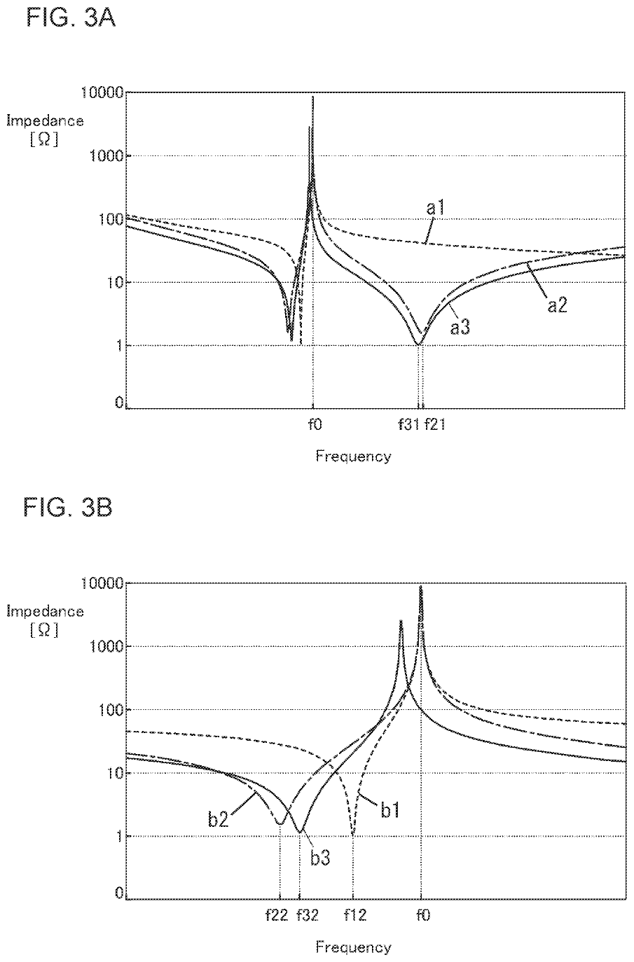

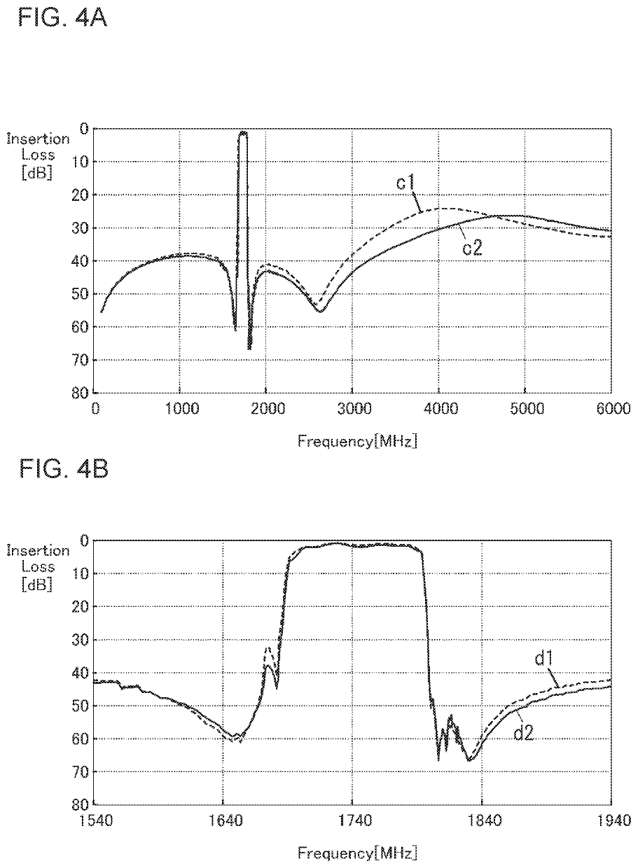

Next, referring to FIG. 3A to FIG. 4B, characteristics of the multiplexer 1 according to the embodiment are described while comparing with characteristics of multiplexers according to comparative examples 1 and 2. The horizontal axis in each of FIG. 3A and FIG. 3B represents the frequency, and the vertical axis in each of FIG. 3A and FIG. 3B represents the impedance. Further, the horizontal axis in each of FIG. 4A and FIG. 4B represents the frequency, and the vertical axis in each of FIG. 4A and FIG. 4B represents the insertion loss.

A dashed line a1 in FIG. 3A and a dashed line b1 in FIG. 3B each illustrates the characteristic of impedance of the first filter 2 of the multiplexer according to the comparative example 1. A dashed-dotted line a2 in FIG. 3A and a dashed-dotted line b2 in FIG. 3B each illustrates the characteristic of impedance of the first filter 2 of the multiplexer according to the comparative example 2. A solid line a3 in FIG. 3A and a solid line b3 in FIG. 3B each illustrate the characteristic of impedance of the first filter 2 of the multiplexer 1 according to the embodiment.

Further, a dashed line c1 in FIG. 4A and a dashed line d1 in FIG. 4B each illustrates the characteristic of insertion loss of the first filter 2 of the multiplexer according to the comparative example 2. A solid line c2 in FIG. 4A and a solid line d2 in FIG. 4B each illustrates the characteristic of insertion loss of the first filter 2 of the multiplexer 1 according to the embodiment.

In the multiplexer according to the comparative example 1, the inductors 4 and 6 and the capacitive element 5 are omitted from the circuit illustrated in FIG. 2. In this case, in the first filter 2, no attenuation pole is formed on the high frequency side above a resonant frequency f0 as illustrated by the dashed line a1 of FIG. 3A. This causes the pass band of the first filter 2 to expand on the high frequency side above the resonant frequency f0, and as a result, there is a problem of allowing a signal to pass even when the signal is in a frequency band to be attenuated. That is to say, the filter characteristics of the first filter 2 degrade. Here, the resonant frequency f0, for example, is included in the frequency band of Band 3.

In the multiplexer according to the comparative example 2, the capacitive element 5 is omitted from the circuit illustrated in FIG. 2. In this case, in the first filter 2, an attenuation pole is formed at a frequency f21, which is higher than the resonant frequency f0, as illustrated by the dashed-dotted line a2 of FIG. 3A. However, in this case, as illustrated by the dashed line b1 and the dashed-dotted line b2 of FIG. 3B, the frequency of an attenuation pole formed on the low frequency side below the resonant frequency f0 changes from a frequency f12 to a frequency f22 (f22<f12). This causes the pass band of the first filter 2 to expand on the low frequency side, and as a result, there is a problem of allowing a signal to pass even when the signal is in a frequency band to be attenuated. Also in this case, the filter characteristics of the first filter 2 degrade. Here, in the multiplexer according to the comparative example 2, the inductance of the inductor 4, for example, is 1.0 nH.

In the multiplexer 1 according to the embodiment, the capacitive element 5 is added to the multiplexer according to the comparative example 2. The first end portion 51 of the capacitive element 5 is connected to the first path S1 at a position in between the first series arm resonator 21 and the second terminal 102, and the second end portion 52 of the capacitive element 5 is connected between the first parallel arm resonator 26 and the inductor 4. In this case, as illustrated by the solid line a3 of FIG. 3A, an attenuation pole is formed at a frequency f31 that is higher than the resonant frequency f0. Further, in this case, as illustrated by the solid line b3 of FIG. 3B, the frequency of an attenuation pole formed on the low frequency side below the resonant frequency f0 changes from a frequency f22 to a frequency f32 (f32>f22). This enables to make the pass band of the first filter 2 narrower than that of the multiplexer according to the comparative example 2 and enables to suppress the degradation in filter characteristics of the first filter 2.

Here, in the multiplexer 1 according to the embodiment, the inductance of the inductor 4, for example, is 0.5 nH, and the electrostatic capacity of the capacitive element 5, for example, is 0.5 pF. That is to say, the multiplexer 1 according to the embodiment enables to reduce the inductance of the inductor 4 by about half, compared with the multiplexer according to the comparative example 2. In short, as in the multiplexer 1 according to the embodiment, it becomes possible to reduce the inductance of the inductor 4 by combining the inductor 4 and the capacitive element 5. Note that the electrostatic capacity of the capacitive element 5 is not limited to 0.5 pF and may be any value less than or equal to 1 pF.

Further, as illustrated in FIG. 4A and FIG. 4B, the multiplexer 1 according to the embodiment enables to have filter characteristics nearly equal to the filter characteristics of the multiplexer according to the comparative example 2.

Note that in the multiplexer 1 according to the embodiment, the first end portion 51 of the capacitive element 5 is connected between the first series arm resonator 21 and the second terminal 102. Alternatively, for example, the first end portion 51 of the capacitive element 5 can be connected between the fifth series arm resonator 25 and the first terminal 101. However, in that case, there is a possibility that the phase of a signal passing through the second filter 3, to which the first terminal 101 is connected, may shift toward a short-circuited direction, and as a result, the filter characteristics of the second filter 3 may degrade. Accordingly, the first end portion 51 of the capacitive element 5 can be connected to the first path S1 at a position in between the second terminal 102 and the fifth series arm resonator 25, which is the closest to the first terminal 101.

### (3) CONCLUSION

### (3.1) Multiplexer

The multiplexer 1 according to the embodiment includes the first terminal 101, the second terminal 102, the first filter 2, the second filter 3, and the capacitive element 5. The first terminal 101 is connected to the antenna 310. The second terminal 102 is connected to the amplifier (power amplifier 111). The first filter 2 and the second filter 3 are connected to the antenna 310 via the first terminal 101. The capacitive element 5 includes the first end portion 51 and the second end portion 52. The first filter 2 includes a plurality of series arm resonators (first to fifth series arm resonators 21 to 25), a plurality of parallel arm resonators (first to fourth parallel arm resonators 26 to 29), and at least one inductor 4. The plurality of series arm resonators are provided on the first path S1 that connects the first terminal 101 and the second terminal 102. The plurality of parallel arm resonators are provided on a plurality of the second paths S21 to S24 that respectively connect a plurality of nodes N1 to N4 on the first path S1 and the ground. At least one inductor 4 is provided between at least one parallel arm resonator (first parallel arm resonator 26) of the plurality of parallel arm resonators and the ground. The first end portion 51 of the capacitive element 5 is connected to the first path S1 at a position in between the second terminal 102 and the series arm resonator (fifth series arm resonator 25) that is the closest to the first terminal 101 among the plurality of series arm resonators. The second end portion 52 of the capacitive element 5 is connected between the parallel arm resonator (first parallel arm resonator 26) and the inductor 4.

In the multiplexer 1 according to the embodiment, the inductor 4 is provided between the first parallel arm resonator 26 and the ground. Further, in the multiplexer 1 according to the embodiment, the first end portion 51 of the capacitive element 5 is connected to the first path S1 at a position in between the fifth series arm resonator 25 and the second terminal 102, and the second end portion 52 of the capacitive element 5 is connected between the first parallel arm resonator 26 and the inductor 4. This enables to improve the filter characteristics of the first filter 2 while suppressing the degradation in filter characteristics of the second filter 3.

Further, in the multiplexer 1 according to the embodiment, the first end portion 51 of the capacitive element 5 is connected to the first path S1 at a position in between the second terminal 102 and the series arm resonator (first series arm resonator 21) that is the closest to the second terminal 102 among the plurality of series arm resonators (first to fifth series arm resonators 21 to 25). This facilitates incorporation of the capacitive element 5 in the first filter 2.

Further, in the multiplexer 1 according to the embodiment, the capacitive element 5 is connected in parallel to two or more resonators (first series arm resonator 21 and first parallel arm resonator 26) including the parallel arm resonator (first parallel arm resonator 26). This enables to reduce the value of the capacitive element 5, and as a result, it becomes possible to alleviate an impact on the insertion loss (loss).

### (3.2) Radio Frequency Circuit

The radio frequency circuit 100 according to the embodiment includes the multiplexer 1, the first amplifier (power amplifier 111), and the second amplifier (low-noise amplifier 121). The first amplifier is the amplifier described above and is connected to the first filter 2. The second amplifier is connected to the second filter 3.

Because the radio frequency circuit 100 according to the embodiment includes the multiplexer 1, the radio frequency circuit 100 according to the embodiment enables to improve the filter characteristics of the first filter 2 while suppressing the degradation in filter characteristics of the second filter 3.

### (3.3) Communication Device

The communication device 300 according to the embodiment includes the radio frequency circuit 100 and the signal processing circuit 301. The signal processing circuit 301 is connected to the radio frequency circuit 100.

Because the communication device 300 according to the embodiment includes the radio frequency circuit 100, the communication device 300 according to the embodiment enables to improve the filter characteristics of the first filter 2 while suppressing the degradation in filter characteristics of the second filter 3.

### (4) MODIFIED EXAMPLES

Hereinafter, modified examples of the embodiment are listed. The modified examples which will be described below can be combined for applications if appropriate.

### (4.1) Modified Example 1

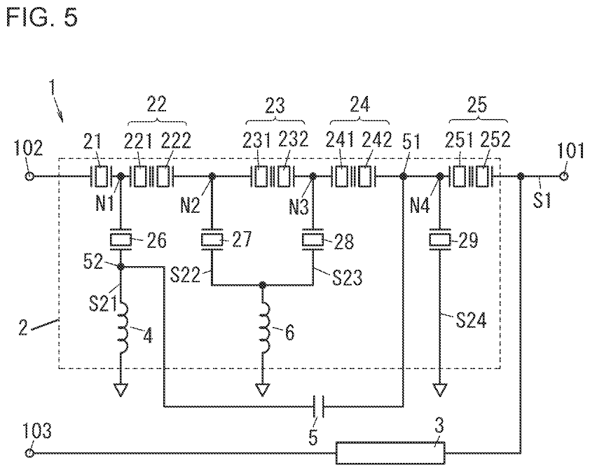

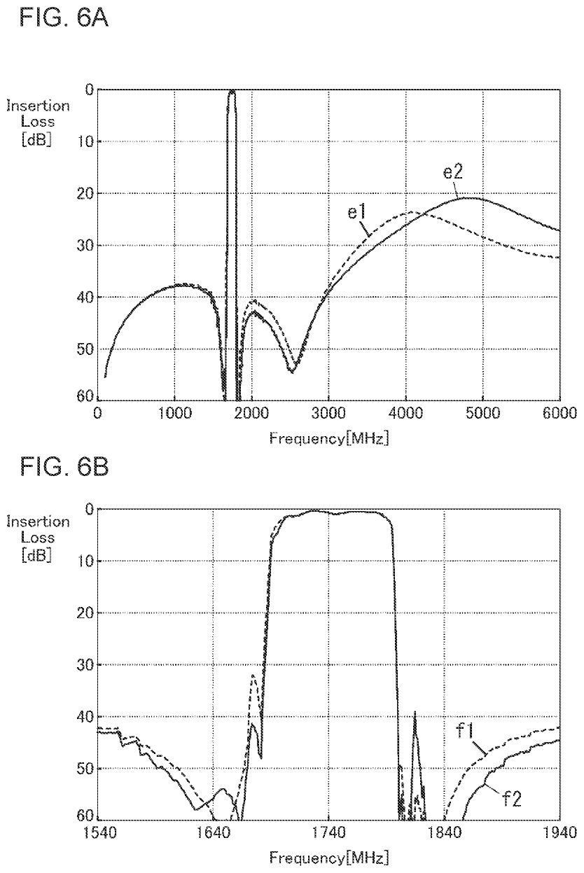

A multiplexer 1 according to a modified example 1 of the embodiment is described with reference to FIG. 5, FIG. 6A, and FIG. 6B. With regard to the multiplexer 1 according to the modified example 1, same reference characters are given to constituent elements similar to those of the multiplexer 1 according to the embodiment, and descriptions thereof are omitted.

The multiplexer 1 according to the modified example 1 is different from the multiplexer 1 according to the embodiment in that the first end portion 51 of the capacitive element 5 is connected to the first path S1 at a position in between the fourth series arm resonator 24 and the fifth series arm resonator 25.

That is to say, in the multiplexer 1 according to the modified example 1, as illustrated in FIG. 5, the first end portion 51 of the capacitive element 5 is connected to the first path S1 at a position in between the fourth series arm resonator 24 and the fifth series arm resonator 25. Further, the second end portion 52 of the capacitive element 5 is connected between the first parallel arm resonator 26 of the plurality of parallel arm resonators and the inductor 4. In short, in the multiplexer 1 according to the modified example 1, the capacitive element 5 is connected in parallel to two or more resonators including the parallel arm resonator 26.

As illustrated in FIG. 6A and FIG. 6B, also in this case, it becomes possible to have filter characteristics nearly equal to the filter characteristics of the multiplexer according to the comparative example 2 described above.

### (4.2) Modified Example 2

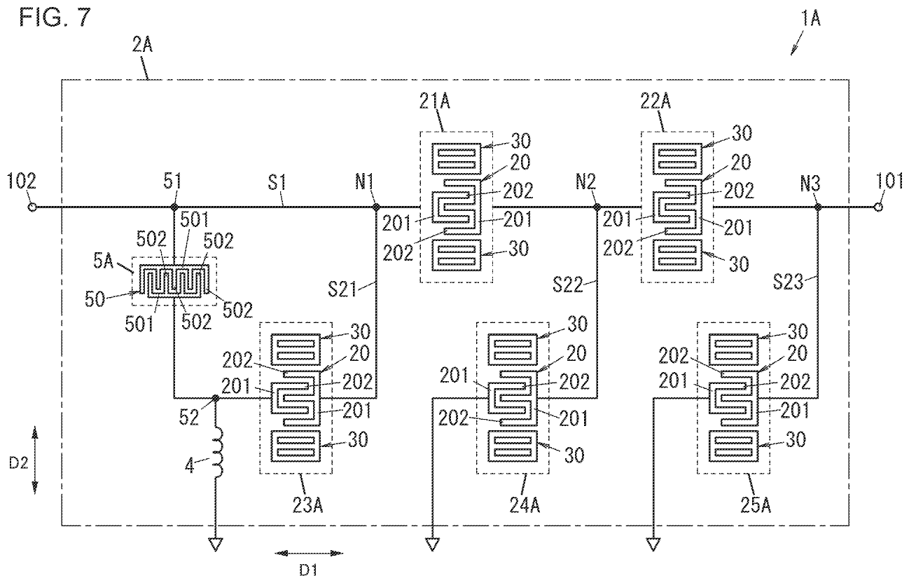

A multiplexer 1A according to a modified example 2 of the embodiment is described with reference to FIG. 7. With regard to the multiplexer 1A according to the modified example 2, same reference characters are given to constituent elements similar to those of the multiplexer 1 according to the embodiment, and descriptions thereof are omitted.

In the multiplexer 1A according to the modified example 2 is different from the multiplexer 1 according to the embodiment in that a capacitive element 5A includes a second IDT electrode 50.

As illustrated in FIG. 7, the multiplexer 1A according to the modified example 2 includes the first terminal 101, the second terminal 102, a first filter 2A, the second filter (not illustrated), and the capacitive element 5A.

The first filter 2A includes a plurality (two in the illustrated example) of series arm resonators, a plurality (three in the illustrated example) of parallel arm resonators, and the inductor 4.

The plurality of series arm resonators include a first series arm resonator 21A and a second series arm resonator 22A. The plurality of series arm resonators are provided on the first path S1 that connects the first terminal 101 and the second terminal 102. The plurality of series arm resonators are connected in series on the first path S1. The plurality of series arm resonators are arranged in the order of, from the second terminal 102 side, the first series arm resonator 21A and the second series arm resonator 22A.

The plurality of parallel arm resonators include a first parallel arm resonator 23A, a second parallel arm resonator 24A, and a third parallel arm resonator 25A. The first parallel arm resonator 23A is provided on the second path S21 between the first node N1 on the first path S1 and the ground. The second parallel arm resonator 24A is provided on the second path S22 between the second node N2 on the first path S1 and the ground. The third parallel arm resonator 25A is provided on the second path S23 between the third node N3 on the first path S1 and the ground.

As illustrated in FIG. 7, each of the plurality of series arm resonators and the plurality of parallel arm resonators includes a first IDT (Interdigital Transducer) electrode 20 and a plurality (two in the illustrated example) of reflectors 30. The first IDT electrode 20 includes two first busbars 201 and a plurality (five in the illustrated example) of first electrode fingers 202.

In the first IDT electrode 20, two first busbars 201 face each other in a first direction D1. Of the plurality of first electrode fingers 202, three first electrode fingers 202 are connected to one of the first busbars 201 (right-hand side of FIG. 7) and extend toward the other of the first busbars 201 (left-hand side of FIG. 7). Further, of the plurality of first electrode fingers 202, the remaining two first electrode fingers 202 are connected to the other of the first busbars 201 and extend toward the one of the first busbars 201. That is to say, in the first IDT electrode 20, each of the plurality of first electrode fingers 202 extends along the first direction D1.

As illustrated in FIG. 7, the capacitive element 5A includes the second IDT electrode 50. The second IDT electrode 50 includes two second busbars 501 and a plurality (nine in the illustrated example) of second electrode fingers 502.

In the second IDT electrode 50, two second busbars 501 face each other in a second direction D2. Of the plurality of second electrode fingers 502, four second electrode fingers 502 are connected to one of the second busbars 501 (lower side of FIG. 7) and extend toward the other of the second busbars 501 (upper side of FIG. 7). Further, of the plurality of second electrode fingers 502, the remaining five second electrode fingers 502 are connected to the other of the second busbars 501 and extend toward the one of the second busbars 501. That is to say, in the second IDT electrode 50, each of the plurality of second electrode fingers 502 extends along the second direction D2. In short, in the multiplexer 1A according to the modified example 2, the plurality of first electrode fingers 202 of the first IDT electrode 20 and the plurality of second electrode fingers 502 of the second IDT electrode 50 cross each other. More specifically, in the multiplexer 1A, the plurality of first electrode fingers 202 and the plurality of second electrode fingers 502 are orthogonal to each other. Here, the term “orthogonal” means to include not only the state where the angle of two objects is precisely 90 degrees but also the state where the angle of two objects is substantially orthogonal within tolerance, which still produces the effects in a substantial manner.

In the multiplexer 1A according to the modified example 2, the first end portion 51 of the capacitive element 5A is connected to the first path S1 at a position in between the first series arm resonator 21A and the second terminal 102. Further, the second end portion 52 of the capacitive element 5A is connected between the first parallel arm resonator 23A and the inductor 4. That is to say, the capacitive element 5A is connected in parallel to the first parallel arm resonator 23A. This facilitates control of capacitance of the capacitive element 5A.

In the multiplexer 1A according to the modified example 2, in all the plurality of series arm resonators and the plurality of parallel arm resonators, the first electrode fingers 202 extend along the first direction D1. However, it is only necessary that at least the first electrode fingers 202 of the first parallel arm resonator 23A extend along the first direction D1. Accordingly, for example, the first electrode fingers 202 of the first series arm resonator 21A may extend along the second direction D2.

### (4.3) Other Modified Examples

The first end portion 51 of the capacitive element 5 only needs to be connected to the first path S1 at a position in between the second terminal 102 and the fifth series arm resonator 25, which is the closest to the first terminal 101. Accordingly, for example, the first end portion 51 of the capacitive element 5 may alternatively be connected to the first path S1 at a position in between the second series arm resonator 22 and the third series arm resonator 23.

The second end portion 52 of the capacitive element 5 may, for example, be connected between the inductor 6 and the resonators, which are the second parallel arm resonator 27 and the third parallel arm resonator 28.

The capacitive element 5 may, for example, be made up of a plurality of capacitors that are connected in parallel to each other.

The number of the series arm resonators is not limited to two or five and may alternatively be three, four, six, or more. Moreover, the number of the parallel arm resonators is not limited to three or four and may alternatively be two, five, or more.

Each of the first filter 2 and the second filter 3 may be a transmission filter, each of the first filter 2 and the second filter 3 may be a reception filter, or the first filter 2 and the second filter 3 may be a reception filter and a transmission filter, respectively.

### ASPECTS

In the present specification, the following aspects are disclosed.

A multiplexer (1;1A) according to a first aspect includes a first terminal (101), a second terminal (102), a first filter (2;2A), a second filter (3), and a capacitive element (5;5A). The first terminal (101) is connected to an antenna (310). The second terminal (102) is connected to an amplifier (111). The first filter (2;2A) and the second filter (3) are connected to the antenna (310) via the first terminal (101). The capacitive element (5;5A) includes a first end portion (51) and a second end portion (52). The first filter (2;2A) includes a plurality of series arm resonators (21 to 25;21A, 22A), a plurality of parallel arm resonators (26 to 29;23A to 25A), and at least one inductor (4). The plurality of series arm resonators (21 to 25;21A, 22A) are provided on a first path (S1) that connects the first terminal (101) and the second terminal (102). The plurality of parallel arm resonators (26 to 29;23A to 25A) are provided on a plurality of second paths (S21 to S24) respectively connecting a plurality of nodes (N1 to N4) on the first path (S1) and ground. The at least one inductor (4) is provided between at least one parallel arm resonator (26;23A) of the plurality of parallel arm resonators (26 to 29;23A to 25A) and the ground. The first end portion (51) of the capacitive element (5;5A) is connected to the first path (S1) at a position in between the second terminal (102) and the series arm resonator (25;22A) that is the closest to the first terminal (101) among the plurality of series arm resonators (21 to 25;21A, 22A). The second end portion (52) of the capacitive element (5;5A) is connected between the parallel arm resonator (26;23A) and the inductor (4).

According to this aspect, it becomes possible to improve filter characteristics of the first filter (2;2A) while suppressing degradation in filter characteristics of the second filter (3).

In a multiplexer (1;1A) according to a second aspect, in the first aspect, the first filter (2;2A) is a transmission filter, and the second filter (3) is a reception filter.

According to this aspect, it becomes possible to improve the filter characteristics of the first filter (2;2A) while suppressing the degradation in filter characteristics of the second filter (3).

In a multiplexer (1;1A) according to a third aspect, in the first or second aspect, the first end portion (51) of the capacitive element (5;5A) is connected to the first path (S1) at a position in between the second terminal (102) and the series arm resonator (21;21A) that is the closest to the second terminal (102) among the plurality of series arm resonators (21 to 25;21A, 22A).

This aspect facilitates incorporation of the capacitive element (5;5A) in the first filter (2;2A).

In a multiplexer (1) according to a fourth aspect, in any one of the first to third aspects, the capacitive element (5) is connected in parallel to two or more resonators (21, 26) including the parallel arm resonator (26).

According to this aspect, it becomes possible to reduce the value of the capacitive element (5) and as a result, it becomes possible to alleviate an impact on the insertion loss (loss).

In a multiplexer (1A) according to a fifth aspect, in any one of the first to third aspects, the capacitive element (5A) is connected in parallel to the parallel arm resonator (23A).

This aspect facilitates capacitance control of the capacitive element (5A).

In a multiplexer (1A) according to a sixth aspect, in any one of the first to fifth aspects, the parallel arm resonator (23A) includes a first IDT electrode (20) including a plurality of first electrode fingers (202) extending along a first direction (D1). The capacitive element (5A) includes a second IDT electrode (50) including a plurality of second electrode fingers (502) extending along a second direction (D2), the second direction (D2) crossing the first direction (D1).

A radio frequency circuit (100) according to a seventh aspect includes the multiplexer (1;1A) according to any one of the first to sixth aspects, a first amplifier (111), and a second amplifier (121). The first amplifier (111) serves as the foregoing amplifier (111) and is connected to the first filter (2;2A). The second amplifier (121) is connected to the second filter (3).

According to this aspect, it becomes possible to improve the filter characteristics of the first filter (2;2A) while suppressing the degradation in filter characteristics of the second filter (3).

A communication device (300) according to an eighth aspect includes the radio frequency circuit (100) according to the seventh aspect and a signal processing circuit (301). The signal processing circuit (301) is connected to the radio frequency circuit (100).

According to this aspect, it becomes possible to improve the filter characteristics of the first filter (2;2A) while suppressing the degradation in filter characteristics of the second filter (3).

### REFERENCE SIGNS LIST

1, 1A Multiplexer
2, 2A First filter
3 Second filter
4 Inductor
5, 5A Capacitive element
6 Inductor
8 External connection terminal
20 First IDT electrode
21 First series arm resonator
22 Second series arm resonator
23 Third series arm resonator
24 Fourth series arm resonator
25 Fifth series arm resonator
26 First parallel arm resonator
27 Second parallel arm resonator
28 Third parallel arm resonator
29 Fourth parallel arm resonator
30 Reflector
50 Second IDT electrode
51 First end portion
52 Second end portion
81 Antenna terminal
82 Signal input terminal
83 Signal output terminal
84 Control terminal
100 Radio frequency circuit
101 First terminal
102 Second terminal
103 Third terminal
104 First switch
105 Second switch
106 Third switch
107 Fourth switch
111 Power amplifier (amplifier, first amplifier)
112A Transmission filter (first filter)
112B, 112C Transmission filter
113 Output matching circuit
114A-114C Matching circuit
115 Controller
121 Low-noise amplifier (second amplifier)
122A Reception filter (second filter)
122B, 122C Reception filter
123 Input matching circuit
132A Duplexer (multiplexer)
132B, 132C Duplexer
140 Common terminal
141-143 Selection terminal
150 Common terminal
151-153 Selection terminal
160 Common terminal
161-163 Selection terminal
170 Common terminal
171, 172 Selection terminal
201 First busbar
202 First electrode finger
221, 231, 241, 251 First segmented resonator
222, 232, 242, 252 Second segmented resonator
300 Communication device
301 Signal processing circuit
302 RF signal processing circuit
303 Baseband signal processing circuit
310 Antenna
501 Second busbar
502 Second electrode finger
D1 First direction
D2 Second direction
N1-N4 Node
S1 First path
S21-S24 Second path

1. A multiplexer comprising:
a first terminal connected to an antenna;
a second terminal connected to an amplifier;
a first filter and a second filter connected to the antenna via the first terminal; and
a capacitive circuit element having a first end and a second end,
wherein the first filter comprises:
a plurality of series arm resonators in a first path, the first path connecting the first terminal and the second terminal,
a plurality of parallel arm resonators, each of the plurality of parallel arm resonators in a different one of a plurality of second paths, the plurality of second paths respectively connecting a plurality of nodes on the first path and ground, and
at least one inductor respectively between at least one of the plurality of parallel arm resonators and ground,
wherein the first end of the capacitive circuit element is connected to the first path at a position between the second terminal and the one of the plurality of series arm resonators that is closest to the first terminal, and
wherein the second end of the capacitive circuit element is connected between the at least one of the plurality of parallel arm resonators and the inductor.

2. The multiplexer according to claim 1,
wherein the first filter is a transmission filter, and
wherein the second filter is a reception filter.

3. The multiplexer according to claim 1, wherein the first end of the capacitive circuit element is connected to the first path at a position between the second terminal and the one of the plurality of series arm resonators that is closest to the second terminal.

4. The multiplexer according to claim 1, wherein the capacitive circuit element is connected in parallel to two or more resonators including the at least one of the plurality of parallel arm resonators.

5. The multiplexer according to claim 1, wherein the capacitive circuit element is connected in parallel to the at least one of the plurality of parallel arm resonators.

6. The multiplexer according to claim 1,
wherein the at least one of the plurality of parallel arm resonators comprises a first interdigital transducer (IDT) electrode comprising a plurality of first electrode fingers extending along a first direction, and
wherein the capacitive circuit element comprises a second IDT electrode comprising a plurality of second electrode fingers extending along a second direction, the second direction crossing the first direction.

7. A radio frequency circuit comprising:
the multiplexer according to claim 1;
the amplifier connected to the first filter; and
a second amplifier connected to the second filter.

8. A communication device comprising:
the radio frequency circuit according to claim 7; and
a signal processing circuit connected to the radio frequency circuit.
